(19) United States
(12) Patent Application Publication
(10) Pub. No.: US 2026/0246230 A1
(43) Pub. Date: Aug. 20, 2026

(54) TWO-DIMENSIONAL GRATING SURFACE-EMITTING LASER ("2D-GRSEL")

(71) Applicant: nLIGHT, Inc., Camas, WA (US)

(72) Inventor: Manoj Kanskar, Portland, OR (US)

(21) Appl. No.: 19/542,433

(22) Filed: Feb. 17, 2026

Related U.S. Application Data
(60) Provisional application No. 63/761,128, filed on Feb. 20, 2025.

(51) Int. Cl. H01S 5/026; H01S 5/028; H01S 5/06; H01S 5/12; H01S 5/183

(52) U.S. Cl. CPC H01S 5/0268; H01S 5/0281; H01S 5/0601; H01S 5/1215; H01S 5/1237; H01S 5/18386; H01S 2302/02; H01S 2303/00

(57) ABSTRACT

A two-dimensional grating surface-emitting laser includes a substrate, a n-cladding layer disposed atop the substrate, a n-waveguide layer disposed atop the n-cladding layer, a p-waveguide layer disposed atop the n-waveguide layer, a quantum well disposed between the n-waveguide layer and the p-waveguide layer, a p-cladding layer disposed atop the p-waveguide layer, a p-contact layer disposed atop the p-cladding layer, and a two-dimensional grating layer disposed at a location. The location is contemplated to be on or within one or more of the enumerated layers. The two-dimensional grating layer includes a plurality of holes arranged in a pattern with a predetermined grating period, defines a first grating zone beneath the p-contact layer, and defines a second grating zone surrounding the first grating zone.

### CROSS-REFERENCE TO RELATED APPLICATION(S)

This application relies on and claims priority benefit of U.S. Provisional Application No. 63/761,128, filed Feb. 20, 2025, the entire contents of which are incorporated herein by reference.

### FIELD OF THE INVENTION

The present disclosure relates to a construction for a diode laser. More specifically, the present invention concerns a construction for a two-dimensional grating surface-emitting laser (“2D-GRSEL”).

### BACKGROUND OF THE INVENTION

It is commonly understood that high power broad area lasers are limited in their power due to the multi-mode operation and filamentation formation due to gain-index coupling.

The output beam of a broad area laser is multimode laser beam that is diffraction limited. More specifically, the multimode laser beam is understood to be diffraction limited by up to >20 times.

Separately, it is understood that single mode lasers based on a ridge waveguide architecture (e.g., Slab-Coupled Optical Waveguide Lasers (“SCOWL”) and Resonant Waveguide Grating (“RWG”) lasers) are limited to a few watts of output power due to facet power loading. Facet power loading may lead to catastrophic optical mirror damage (“COMD”) when operated at higher output power(s).

Single mode lasers also suffer from low efficiency, because single mode lasers are hindered by a series resistance that is up to five times (5×) larger than the series resistance associated with broad area lasers. The increased series resistance is due to a very narrow device geometry that is employed for operation of single mode laser.

In view of these deficiencies, among others, a need has developed for a broad area semiconductor laser having an emitter width that is much larger than that of a conventional, single mode laser.

Conventional, single mode lasers typically have an emitter with a width that is between 3-10 microns (μm), as measured across the lateral dimension of the emitter. The emitters in convention, single mode lasers also typically have lengths that are a few millimeters long.

It is also known that conventional, single mode lasers produce a nearly diffraction limited beam.

### SUMMARY OF THE INVENTION

The present invention addresses one or more of the deficiencies in the prior art.

In one aspect, the present invention is directed to one or more two-dimensional grating surface-emitting lasers (“2D-GRSELs”) with emitters having dimensions larger than the dimensions known for prior art emitters.

In one or more contemplated examples of the two-dimensional grating surface-emitting laser of the present invention, the dimensions of the laser emitters are hundreds of micrometers to a few millimeters in one direction and one to ten millimeters in the orthogonal direction. Despite these large dimensions, the laser emitters are contemplated to produce a high quality laser beam that is near diffraction limited.

In one embodiment, the present invention provides a two-dimensional grating surface-emitting laser. The laser includes a substrate, a n-cladding layer disposed atop the substrate, a n-waveguide layer disposed atop the n-cladding layer, a p-waveguide layer disposed atop the n-waveguide layer, a quantum well disposed between the n-waveguide layer and the p-waveguide layer, a p-cladding layer disposed atop the p-waveguide layer, a p-contact layer disposed atop the p-cladding layer, and a two-dimensional grating layer. The two dimensional grating layer is disposed at a location including, but not limited to, atop the p-cladding layer, buried within the p-cladding layer, between the p-cladding layer and the p-waveguide layer, buried within the p-waveguide layer, buried within the n-waveguide layer, beneath the n-waveguide layer, between the n-cladding layer and the n-waveguide layer, buried within the n-cladding layer, and beneath the n-cladding layer. The two-dimensional grating layer includes a plurality of holes arranged in a pattern with a predetermined grating period, defines a first grating zone beneath the p-contact layer, and defines a second grating zone surrounding the first grating zone.

In one contemplated embodiment, each of the plurality of holes are filled with air.

In another contemplated embodiment, each of the plurality of holes are filled with a semiconductor material with an index of refraction differing from an index of refraction of the two-dimensional grating layer.

Still further, it is contemplated that each of the plurality of holes are filled with metal.

In the two-dimensional grating surface-emitting laser of the present invention, the first grating zone is contemplated to define a pumped region that generates laser light.

Separately, the second grating zone may define an unpumped region that does not generate laser light.

A third grating zone may be provided that surrounds the second grating zone. The third grating zone defines an absorber region that absorbs laser light.

In one contemplated embodiment of the present invention, the predetermined grating period in the first grating zone has a first predetermined period Pₓ in a first direction and a second predetermined period P_{y} in a second direction, orthogonal to the first direction, Pₓ=P_{y}=λ/n, λ is the wavelength in vacuum, and n is the effective index of the lasing mode.

In another contemplated embodiment, the predetermined grating period in the second grating zone has a first predetermined period Pₓ in a first direction and a second predetermined period P_{y} in a second direction, orthogonal to the first direction, Pₓ=P_{y}=λ/2n, λ is the wavelength in vacuum, and n is the effective index of the lasing mode.

In yet another contemplated embodiment, the predetermined grating period has a first predetermined period Pₓ in a first direction and a second predetermined period P_{y} in a second direction, orthogonal to the first direction, Pₓ=λ/n, P_{y}=λ/2n, λ is the wavelength in vacuum, and n is the effective index of the lasing mode.

Still further, it is contemplated that, in at least one of the first and second grating zone, the predetermined grating period has a first predetermined period Pₓ in a first direction and a second predetermined period P_{y} in a second direction, orthogonal to the first direction, Pₓ=P_{y}=λ/n, λ is the wavelength in vacuum, and n is the effective index of the lasing mode.

Alternatively, in at least one of the first and second grating zones, the predetermined grating period has a first predetermined period Pₓ in a first direction and a second predetermined period P_{y} in a second direction, orthogonal to the first direction, Pₓ=λ/n, P_{y}=λ/2n, λ is the wavelength in vacuum, and n is the effective index of the lasing mode.

In yet another variation, in the first grating zone, the predetermined grating period has a first predetermined period Pₓ in a first direction and a second predetermined period P_{y} in a second direction, orthogonal to the first direction, Pₓ=P_{y}=N/n, λ is the wavelength in vacuum, and n is the effective index of the lasing mode. In the second grating zone, the predetermined grating period has a third predetermined period Pₓ in a first direction and a fourth predetermined period P_{y} in the second direction, and Pₓ=P_{y}=λ/2n.

The present invention also contemplates that, in the first grating zone, the predetermined grating period has a first predetermined period Pₓ in a first direction and a second predetermined period P_{y} in a second direction, orthogonal to the first direction, Pₓ=P_{y}=N/n, λ is the wavelength in vacuum, and n is the effective index of the lasing mode. In the second grating zone, the predetermined grating period has a third predetermined period Pₓ in a first direction and a fourth predetermined period P_{y} in the second direction, and Pₓ=N/n, and P_{y}=λ/2n.

In another contemplated embodiment, the waveguide defines a length L in a first direction, the waveguide defines a width W in a second direction, orthogonal to the first direction, and the waveguide defines an aspect ratio m, where L/W>m and m>1. Here, m may be within a range from 1 to 20 and W may be within a range of 0.1 mm to 1 mm.

The present invention also encompasses a two-dimensional grating surface-emitting laser that includes an anti-reflective coating on at least a portion of a bottom surface of the substrate.

In still another contemplated embodiment, the two-dimensional grating surface-emitting laser according to the present invention may include another p-contact layer disposed atop the p-cladding layer. The another p-contact layer is contemplated to be disposed in a side-by-side relationship to the p-contact layer, thereby establishing a coherently coupled configuration. Here, the two-dimensional grating layer defines another first grating zone beneath the another p-contact layer and the two-dimensional grating layer defines another second grating zone surrounding the another first grating zone.

In further embodiments, it is contemplated that the two-dimensional grating layer comprises an index of refraction modulation that is either one dimensional or two dimensional.

Other features and advantages of the present invention will be made apparent from the discussion that follows.

### BRIEF DESCRIPTION OF THE DRAWINGS

The present invention is described in connection with the drawing appended hereto, in which:

FIG. 1 is a perspective, top view of a first embodiment of a 2D-GRSEL according to the present invention;

FIG. 2 is a cross-section of the 2D-GRSEL illustrated in FIG. 1, with the cross-section being taken along the longitudinal direction of the 2D-GRSEL illustrated in FIG. 1;

FIG. 3 is an enlarged detail of a portion of the cross-section provided in FIG. 2;

FIG. 4 is a perspective, bottom view of the 2D-GRSEL illustrated in FIG. 1;

FIG. 5 is a graphical representation of a first pattern for a two-dimensional grating incorporated into one or more embodiments of the 2D-GRSEL according to the present invention;

FIG. 6 provides graphical representations of eight patterns for the shapes of the holes in the two-dimensional grating incorporated into one or more of the embodiments of the 2D-GRSEL of the present invention;

FIG. 7 is a graphical representation of a second pattern for a two-dimensional grating incorporated into one or more embodiments of the 2D-GRSEL according to the present invention;

FIG. 8 is a perspective, cross-sectional view of a second embodiment of a 2D-GRSEL according to the present invention; and

FIG. 9 is a perspective view of a third embodiment of a 2D-GRSEL according to the present invention.

### DETAILED DESCRIPTION OF EMBODIMENT(S) OF THE INVENTION

The present invention will now be described in connection with several examples and embodiments. The present invention should not be understood to be limited solely to the examples and embodiments discussed. To the contrary, the discussion of selected examples and embodiments is intended to underscore the breadth and scope of the present invention, without limitation. As should be apparent to those skilled in the art, variations and equivalents of the described examples and embodiments may be employed without departing from the scope of the present invention.

In addition, aspects of the present invention will be discussed in connection with specific materials and/or components. Those materials and/or components are not intended to limit the scope of the present invention. As should be apparent to those skilled in the art, alternative materials and/or components may be employed without departing from the scope of the present invention.

In the illustrations appended hereto, for convenience and brevity, the same reference numbers are used to refer to like features in the various examples and embodiments of the present invention. The use of the same reference numbers for the same or similar structures and features is not intended to convey that each element with the same reference number is identical to all other elements with the same reference number. To the contrary, the elements may vary from one embodiment to another without departing from the scope of the present invention.

Still further, in the discussion that follows, the terms “first,” “second,” “third,” etc., may be used to refer to like elements. These terms are employed to distinguish like elements from similar examples of the same elements. For example, one fastener may be designated as a “first” fastener to differentiate that fastener from another fastener, which may be designated as a “second fastener.” The terms “first,” “second,” “third,” are not intended to convey any particular hierarchy between the elements so designated.

It is noted that the use of “first,” “second,” and “third,” etc., is intended to follow common grammatical convention. As such, while a component may be designated as “first” in one instance, that same component may be referred to as “second, “third,” etc., in a separate instance. The use of “first,” “second,” and “third,” etc., therefore, is not intended to limit the present invention.

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items. The systems, apparatus, and methods described herein should not be construed as limiting in any way. Instead, the present disclosure is directed toward all novel and non-obvious features and aspects of the various disclosed embodiments, alone and in various combinations and sub-combinations with one another. The term “or” refers to “and/or,” not “exclusive or” (unless specifically indicated).

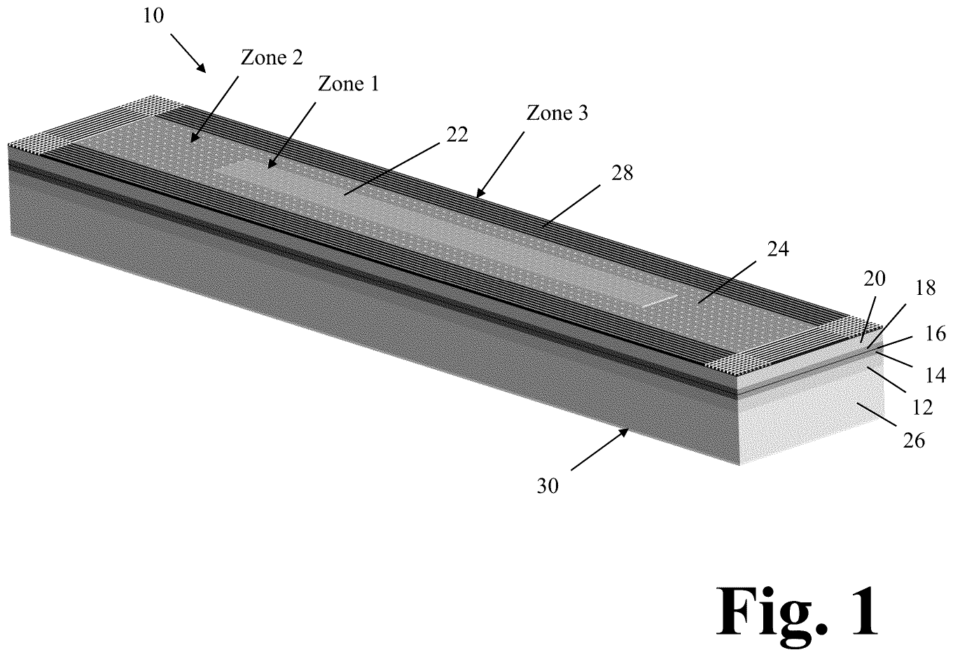

FIG. 1 is a perspective, top view of a two-dimensional grating surface-emitting laser (“2D-GRSEL”) 10 according to the present invention.

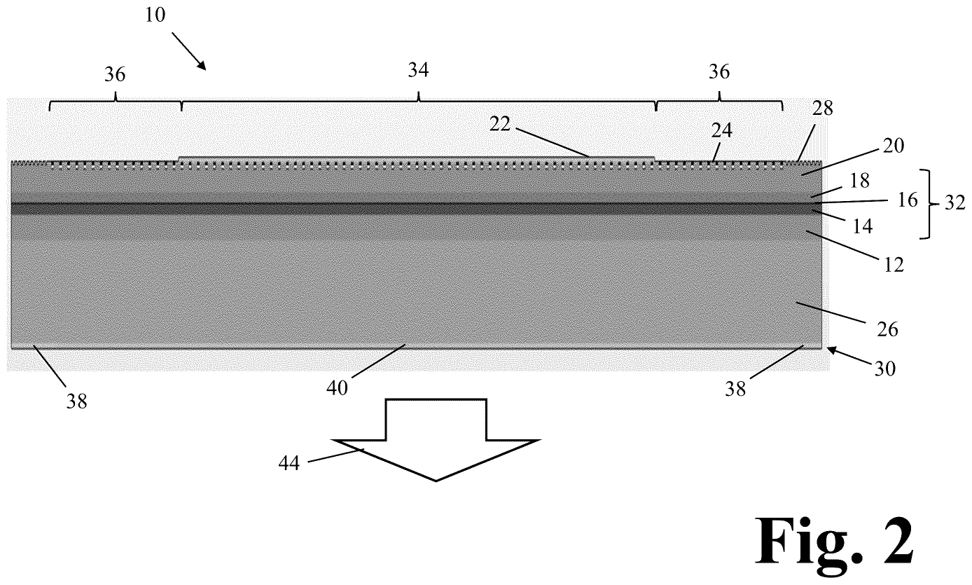

FIG. 2 is a longitudinal cross-section of the 2D-GRSEL 10 illustrated in FIG. 1. The longitudinal cross-section is taken through a mid-section of the 2D-GRSEL 10.

As shown in FIG. 1 and in FIG. 2, the 2D-GRSEL 10 encompasses a p-i-n semiconductor quantum-well slab waveguide laser. The 2D-GRSEL 10 includes an n-cladding layer 12, an n-waveguide layer 14, a quantum well 16, a p-waveguide layer 18, a p-cladding layer 20, a p-contact layer 22, and a two-dimensional grating 24, all of which are disposed on a substrate 26. The 2D-GRSEL 10 also includes an absorber layer 28 that is disposed atop the p-cladding layer 20, at the periphery of the 2D-GRSEL 10. In addition, the 2D-GRSEL 10 includes a patterned n-metal layer 30 beneath the substrate. The substrate 26 lies between the patterned n-metal layer 30 and the n-cladding layer 12.

It is noted that the compositions of the n-cladding layer 12, the n-waveguide layer 14, the p-waveguide layer 18, and the p-cladding layer 20 are known to those skilled in the art. Accordingly, further details concerning the compositions of these layers are not provided herein.

The thicknesses of the n-cladding layer 12, the n-waveguide layer 14, the p-waveguide layer 18, and the p-cladding layer 20 and the indices of refraction of the n-cladding layer 12, the n-waveguide layer 14, the p-waveguide layer 18, and the p-cladding layer 20 are contemplated so that the fundamental mode has a predetermined index coupling with the two-dimensional grating 24. This index coupling is within the level of skill in the art and, therefore, is not discussed further herein.

In various embodiments of the present invention, the two-dimensional grating 24 is placed on the surface of the p-cladding layer 20 as illustrated in FIG. 1. Alternatively, the two-dimensional grating 24 may be buried so that the two-dimensional grating 24 is located within the p-cladding layer 20. Still further, it is contemplated that the two-dimensional grating 24 may be positioned atop the p-waveguide layer 18, between the p-cladding layer 20 and the p-waveguide layer 18. And, in yet another contemplated embodiment, the two-dimensional grating 24 may be within the p-waveguide layer 18. It is noted that the two-dimensional grating 24 may be partially buried and/or partially disposed in one or more of the p-cladding layer 20 and/or the p-waveguide layer 18.

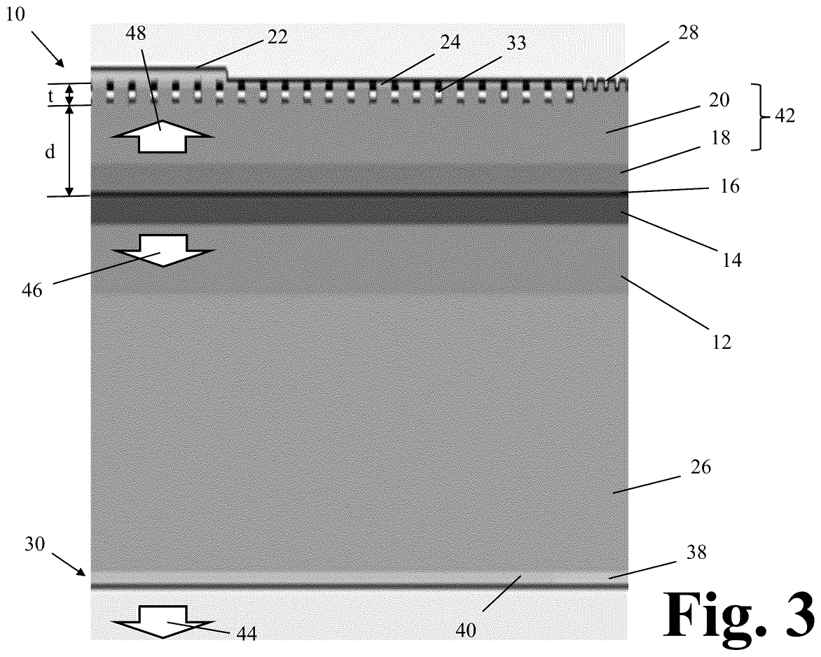

In the embodiments described herein, the bottom of the two-dimensional grating 24 is located at a distance, d, from the quantum well 16. The distance d is illustrated in FIG. 3.

The magnitude of the distance d is contemplated to be in a range of about 50 nm to about 2000 nm. Specific ranges for the distance d are contemplated to be about 50 nm to 1500 nm, about 100 nm to about 400 nm, 200 nm to about 300 nm, and about 250 nm. In other embodiments, it is contemplated that the distance d may be any value, taken in 25 nm increments, from about 50 nm to about 2000 nm without departing from the scope of the present invention. For example, a range for the distance d may be 325 nm-375 nm in one example. In another example, a range for the distance d may be 150 nm-425 nm. In yet another example, the range for the distance d may be 1900-2000 nm.

While details concerning the two-dimensional grating 24 are provided hereinbelow, it is noted that the two-dimensional grating 24 comprises a semiconductor material with a predetermined index of refraction. As a grating, the two-dimensional grating 24 also includes a plurality of holes 33 therethrough. In one embodiment, the holes 33 may be filled, partially or completely, with a semiconductor material with an index of refraction different from the index of refraction of the semiconductor material selected for the two-dimensional grating 24. In other contemplated embodiments, the holes 33 in the two-dimensional grating 24 may not include another semiconductor material. Here, the holes 33 in the two-dimensional grating 24 may be defined by an absence of a semiconductor material. In one contemplated embodiment, the holes 33 are contemplated to be filled with air. In other words, the holes 33 do not contain any semiconductor material. In yet another contemplated embodiment, the holes 33 may be filled with a metal or a metal alloy.

When buried, the two-dimensional grating 24 is contemplated to establish a contrast between the index of refraction of the semiconductor material forming the two-dimensional grating 24 and the semiconductor material forming the layer in which the two-dimensional grating 24 is buried. The index contrast is formed either by using two types of semiconductor materials with different indices of refraction or by forming air holes 33 in the semiconductor material comprising the two-dimensional grating 24.

In the embodiment where the holes 33 in the two-dimensional grating 24 are air holes 33, it is contemplated that the holes 33 may be formed in the two-dimensional grating 24 via a suitable patterning and etching method such as Reactive Ion Etching (“RIE”), Inductively Coupled Plasma (“ICP”), etc. The remaining layers of the 2D-GRSEL 10 may then be grown and/or regrown in a manner known to those skilled in the art.

It is noted that the 2D-GRSEL 10 of the present invention is not contemplated to be limited by any particular manufacturing methodology. Any of a number of manufacturing techniques may be employed without departing from the scope of the present invention.

For discussion purposes, the waveguide 32 of the 2D-GRSEL 10 of the present invention encompasses at least the n-waveguide layer 14, the quantum well 16 and the p-waveguide layer 18, as should be apparent to those skilled in the art.

The pumped region 34 is defined, at least in part, by the p-contact layer 22, as also should be apparent to those skilled in the art. The pumped region 34 generally is understood to encompass the region that generates the laser light 44. It is noted, however, as should be apparent to those skilled in the art, that reference to the pumped region 34 is merely a convention employed by those skilled in the art. The actual region that generates laser light is not limited solely to the footprint of the p-contact layer 22.

With reference to FIG. 2, it is noted that the pumped region 34 is centrally located on the 2D-GRSEL 10 such that unpumped regions 36 are equally defined on either side thereof. It is noted that a symmetrical arrangement of the pumped region 34 versus the unpumped regions 36 is merely illustrative of one non-limiting embodiment of the present invention. The unpumped regions 36 may surround the pumped region 34 in an asymmetric relationship without departing from the scope of the present invention.

As illustrated in FIG. 2, the two-dimensional grating 24 extends across the pumped region 34 and the unpumped region(s) 36. The two-dimensional grating 24 is disposed beneath the p-contact layer 22.

It is noted that the two-dimensional grating 24 may extend beneath the absorber layer 28. If so, the two-dimensional grating 24 under the absorber layer is unpumped. In the embodiment illustrated in FIGS. 1-4, however, the two-dimensional grating 24 does not extend under the absorber layer 28. Instead the two-dimensional grating 24 terminates at the interface with the absorber layer 28.

It is noted that the p-contact layer 22 also may be referred to as the p-metal contact layer 22. The p-contact layer 22 is contemplated to be metal or an alloy, as should be apparent to those skilled in the art.

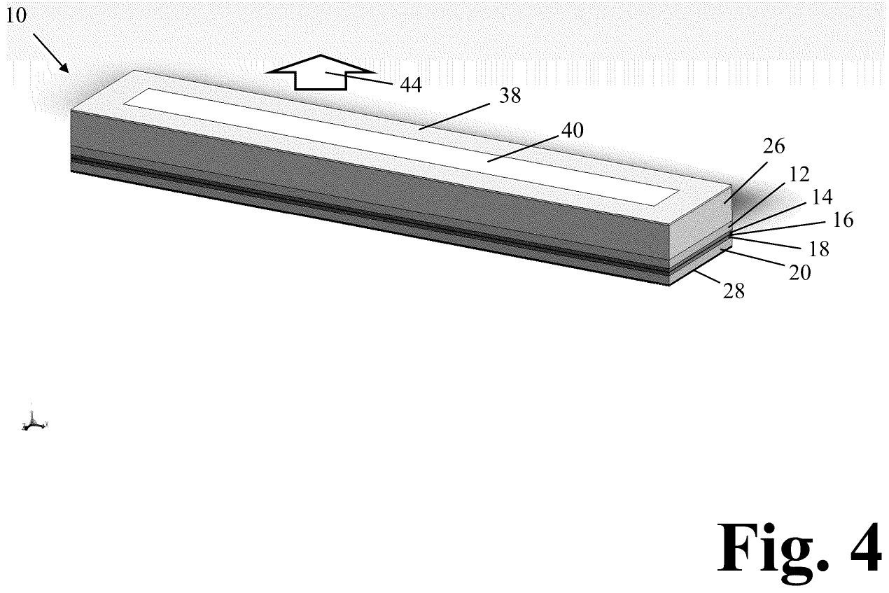

FIG. 4 is a perspective illustration of a bottom view of the 2D-GRSEL 10 of the present invention. Here, a patterned n-metal layer 38 and an antireflective (“AR”) coating 40 are illustrated. Together, the patterned n-metal layer 38 and the AR coating 40 define the n-metal layer 30 at the bottom of the substrate 26.

For purposes of the present invention, the two-dimensional grating 24 in the pumped region 34 is configured so that the laser light 46, 48 oscillates in the plane of the waveguide 32. In addition, the output beam 44 from the 2D-GRSEL 10 diffracts out of the waveguide 32 in a direction that is normal to the plane of the waveguide 32 due to the scattering symmetry of the 2nd order two-dimensional grating 24. As such, a first portion 46 of the laser beam 44 diffracts towards the substrate 26 while a second portion 48 of the laser beam 44 diffracts in the opposite direction, towards the superstrate 42, i.e., in the direction opposite to the +1 diffraction order.

Here, the superstrate 42 refers to the layers disposed atop the quantum well 16. As such, the superstrate 42 includes, but is not limited to, the p-waveguide layer 18 and the p-cladding layer 20.

For the 2D-GRSEL 10, the second portion 48 of the laser beam 44 that is directed towards the superstrate 42 is reflected by the p-metal contact layer 22. The two portions of the laser beam 46, 48 then coherently combine to form a single laser beam 44 that is directed towards the substrate 26 and exits from the substrate 26 through the anti-reflection (“AR”) coating 40. In this configuration, the AR coating 40 defines a window through which the output laser beam 44 exits from the 2D-GRSEL 10.

There are a number of ways in which the 2D-GRSEL 10 of the present invention may be constructed. The following examples detail a few, non-limiting ways in which the 2D-GRSEL 10 of the present invention may be made.

In a first example, which is referred to as a semiconductor-on-semiconductor grating, the 2D-GRSEL 10 is partially grown.

Specifically, with reference to the two-dimensional grating 24, using a lithographic methodology involving, for example, an e-beam, laser holography, or nano-imprint lithography (“NIL”) technology, a mask (not shown) is formed on the p-cladding layer 20. The mask has the two-dimensional pattern desired for the two-dimensional grating 24. After the mask is deposited on the p-cladding layer 20, the p-cladding layer 20 is etched to a depth of thickness, t. This is illustrated, for example, in FIG. 3. After etching, another semiconductor material with a higher or a lower index of refraction is subsequently grown to form the two-dimensional grating 24, thereby establishing an index modulation within the 2D-GRSEL 10.

While not limiting of the present invention, the depth thickness, t, is in the range of 10-300 nm. The thickness t also may fall within a range of 50-250 nm, 100-200 nm, or be about 150 nm.

It is contemplated that the pattern for the two-dimensional grating 24 may be formed on the entire surface of the p-cladding layer 20. However, the light emitting area is defined by the p-contact layer 22 deposited thereon and the pumped region 34.

In a second example, the semiconductor laser structure is, again, contemplated to be fully grown. Using lithographic processes including, but not limited to, an e-beam, laser holography, or nano-imprint lithography (“NIL”) technology, a patterned mask (not shown) may be formed on the p-cladding layer 20. The mask is contemplated to have the desired pattern for the two-dimensional grating 24. Using this mask, the p-cladding layer 20 is etched to a thickness, such as the thickness t. Subsequently, a metal such as gold or copper is deposited to fill the etched holes 33 in the p-cladding layer 20. This helps to form the index modulation for the 2D-GRSEL 10. This type of grating is referred to as semiconductor-metal grating.

In this second example, the unpumped region 36 is contemplated to be provided with an interposing dielectric to prevent any electrical contact to the index modulated areas, which include the areas including the two-dimensional grating 24. Alternatively, the unpumped region 36 may be provided with only a Schottky contact whereas the pumped region 34 may be provided with an Ohmic contact. The index modulation pattern of the two-dimensional grating 24 is contemplated to be formed on the entire surface of the p-cladding layer 20. However, the light emitting area is defined by the p-contact layer 22 and the pumped region 34.

In a third example, the semiconductor laser structure is, again, contemplated to be fully grown. Using lithographic processes including, but not limited to, an e-beam, laser holography, or nano-imprint lithography (“NIL”) technology, a patterned mask (not shown) may be deposited onto the p-cladding layer 20. The mask is contemplated to possess a pattern suitable for formation of the two-dimensional grating 24.

As before, using the mask, the p-cladding layer 20 is etched to a desired thickness t. Subsequently, a dielectric material such as silicon dioxide, silicon nitride, aluminum nitride, or aluminum oxide, is deposited to fill the etched holes 33 in the p-cladding layer 20 to form the appropriate combination of materials to establish index modulation. This type of grating is referred to as semiconductor-oxide grating.

In this case, the unpumped region 36 is contemplated to be provided with an interposing dielectric to prevent any electrical contact to the index modulated areas defined by the two-dimensional grating 24. The two-dimensional grating 24 is contemplated to be formed on the entire surface of the p-cladding layer 20. The light emitting area is defined by the p-contact layer 22 and the pumped region 34.

In the foregoing examples, it is noted that the two-dimensional grating 24 is formed on the p-cladding layer 20. However, as indicated above, the present invention is not limited solely to this construction. In particular, the two-dimensional grating 24 may be embedded/buried, for example, in the p-cladding layer 20, may be disposed atop the surface of the p-waveguide layer 18, or may be embedded/buried in the p-waveguide layer 18. If so, the three masking and etching methodologies described above are contemplated to be adjusted in a manner as should be apparent to those skilled in the art.

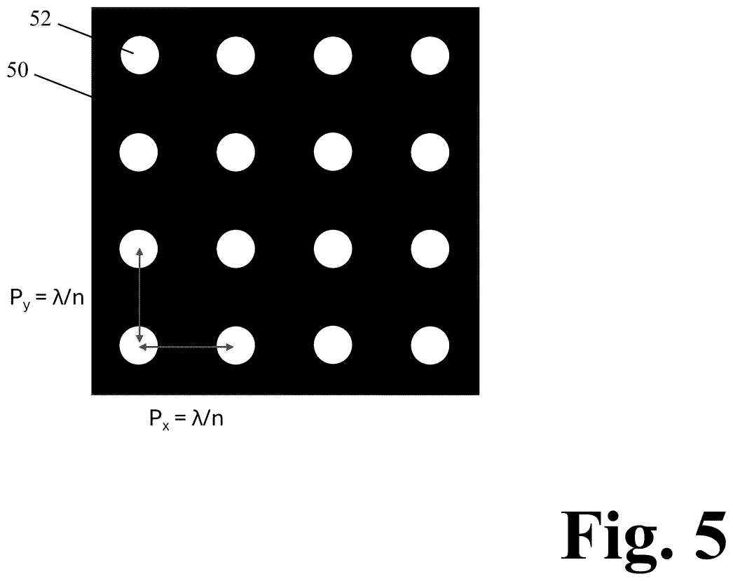

FIG. 5 is a graphical illustration of one contemplated embodiment of a two-dimensional grating 50 according to the present invention. The two-dimensional grating 50 represents one possible configuration for the two-dimensional grating 24 discussed in connection with FIGS. 1-4.

Specifically, FIG. 5 illustrates a two-dimensional grating 50 with a pattern of holes 52. The center-to-center spacing between the holes 52 is referred to as the grating period. In this embodiment, the x-direction and y-direction will be referred to as, Pₓ and P_{y}, respectively. Here, Pₓ=P_{y}=λ/n, where λ is the wavelength in vacuum and n is the effective index of the lasing mode. A fill-factor defined as a ratio of the cross-sectional area of the pattern compared to the unit cell area, i.e., (Pₓ×P_{y}) within a non-limiting range of 0.1 to 0.8 fraction is considered appropriate for the illustrated embodiment. Other ranges for the fill-factor include, but are not limited to, 0.2-0.7, 0.3-0.6, and 0.4-0.5. Moreover, each endpoint may define a range with any other endpoint, as should be apparent to those skilled in the art.

It is noted that the shape and/or configuration of the holes 33, 52 in the two-dimensional grating 24, 50 may be varied without departing from the scope of the present invention.

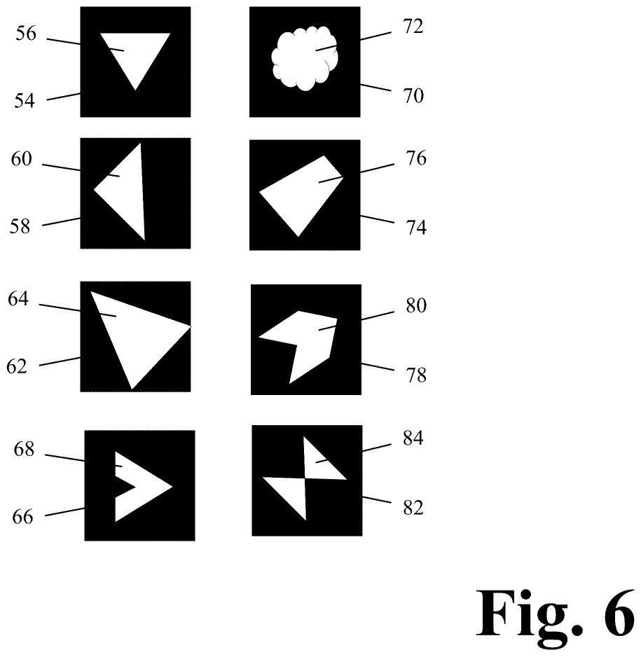

FIG. 6 illustrates eight variations of two-dimensional gratings 54, 58, 62, 66, 70, 74, 78, 82 with eight different configurations for holes 56, 60, 64, 68, 72, 76, 80, 84. These embodiments are merely exemplary and are illustrative of the many configurations for the holes that are contemplated to fall within the scope of the present invention.

In connection with the holes. It is noted that the configurations for the holes 56, 60, 64, 68, 72, 76, 80, 84 may provide superior single mode results by comparison with circular holes. In other words, non-circular holes are contemplated to be better than circular holes within the context of the present invention.

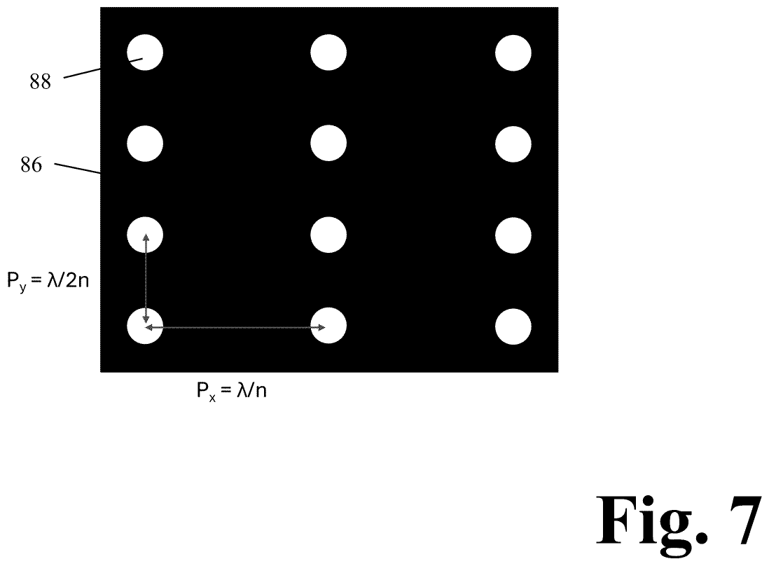

FIG. 7 illustrates another contemplated embodiment for a two-dimensional grating 86 having a plurality of holes 88 therein. As discussed in connection with FIG. 6, the grating period P in the x-direction and y-direction are referred to as, Pₓ and P_{y}, respectively. In this instance, Pₓ=N/n and P_{y}=λ/2n, where λ is the wavelength in vacuum and n is the effective index of the mode. In this embodiment, the x-direction refers to the length L of the device and the y-direction refers to the width W of the device. It is contemplated that the length L and the width W of the device define an aspect ratio, m, where L/W>m. In this embodiment, m>1. Moreover, it is contemplated that the aspect ratio m ranges from 1 to 20. It is also contemplated that the width W is within a range of 0.1 mm to 1 mm.

With renewed reference to FIG. 1, it is noted that the two-dimensional grating 24 of the 2D-GRESEL 10 may be described in connection with three zones.

Grating Zone 1 is defined as the area of the two-dimensional grating 24 over which p-contact layer 22 is disposed. As noted above, laser light 44, 46, 48 is generated underneath Grating Zone 1 due to stimulated emission of radiation from the recombination of injected bipolar carriers. This is also referred to as the pumped region 34.

Grating Zone 2 is defined as the area around the perimeter of Grating Zone 1. Grating Zone 2 has no electrical contact to the underlying semiconductor laser. Therefore, no laser light 44, 46, 48 is generated in Grating Zone 2. Grating Zone 2 also is referred to herein as the unpumped region 36.

Typically, some light will leak out of Grating Zone 1 into Grating Zone 2 due to oscillation in the plane of the waveguide. The leaked light will scatter orthogonally out of the plane as previously described due to #1 diffraction. Here, the AR coating 40 is contemplated to be sized properly to ensure that light is not blocked and exits to form part of the output laser beam 44.

Grating Zone 3 is defined as the outside area around the perimeter of Grating Zone 2. Grating Zone 3 has no electrical contact to the underlying semiconductor laser therefore no light is generated in Grating Zone 3. Grating Zone 3 provides an absorbing layer so that any residual light that reaches this zone is absorbed and not reflected back into the laser cavity to cause instability in the quality of the output laser beam 44.

For the 2D-GRSEL 10 illustrated in FIG. 1, it is contemplated that the two-dimensional grating 24 has a uniform two-dimensional grating 50, 86 consistent with the embodiments illustrated in FIGS. 5 and 7, for example. Any of the patterns illustrated in FIG. 6 may be employed with these embodiments, as noted. These embodiments are referred to as Case 1.

The present invention also contemplates one or more embodiments that are referred to as Case 2 herein.

For the embodiment(s) encompassed by Case 2, it is contemplated that Grating Zone 1 includes the two-dimensional grating 50 illustrated in FIG. 5 or the two-dimensional grating 86 illustrated in FIG. 7. It is also contemplated that Grating Zone 2 has a two-dimensional grating pattern with a grating period P satisfying the conditions Pₓ=λ/2n and P_{y}=λ/2n. Moreover, in Case 2, the 2D-GRSEL 10 has a Pₓ=N/n and P_{y}=W/n in the pumped region 34 and a Pₓ=λ/2n and P_{y}=λ/2n in the surrounding region that is not electrically pumped (the unpumped region 36; Grating Zone 2). In Case 2, the absorber layer 28 covering Grating Zone 3 is contemplated to have either a 1D or a 2D grating with Pₓ=λ/2n and P_{y}=λ/2n or not. In Case 2, the x-direction is the length L of the device and y-direction is the width W of the device. In this embodiment, the aspect ratio of L/W>m. Here, the aspect ratio m satisfies the condition m>1. It is contemplated that the aspect ratio m falls within a range from 1 to 20. The width Wis contemplated to fall within a range of 0.1 mm to 1 mm.

The present invention also contemplates a Case 3 for the 2D-GRSEL 10.

Case 3 encompasses an arrangement where Grating Zone 1 and Grating Zone 2 have the grating patterns illustrated in either one of FIGS. 5 and 7. Here, Grating Zone 3 has a one-dimensional grating pattern with Pₓ=λ/2n and P_{y}=λ/2n. A one-dimensional grating pattern involves grating lines in multiple rows as in the two-dimensional grating pattern.

For Case 3, the 2D-GRSEL 10 has a two-dimensional grating 24 with a grating period P where Pₓ=λ/n and P_{y}=λ/n in Grating Zone 1 (the pumped region 34). In Grating Zone 2, it is contemplated that the two-dimensional grating 24 has a configuration where the grating period P satisfies the conditions Pₓ=N/n and P_{y}=λ/n. In Grating Zone 3, which encompasses the surrounding region that is not electrically pumped, the absorber layer 28 that covers this region is contemplated to have a configuration with either a 1D or a 2D grating, where Pₓ=λ/2n and P_{y}=λ/2n or not.

Case 3 encompasses a configuration with a 1D grating having a grating period P=λ/2n. Here, the x-direction is the length L of the device and the y-direction is the width W of the device. The aspect ratio m satisfies the condition that L/W>m. Here, m>1. The aspect ratio m may fall within a range from 1 to 20. The width W is contemplated to fall within a range of 0.1 mm to 1 mm.

As noted above, the 2D-GRESL 10 of the present invention is contemplated to encompass one or more embodiments where the two-dimensional grating 24 is disposed atop the p-cladding layer 20, buried in the p-cladding layer 20, disposed between the p-cladding layer 20 and the p-waveguide layer 18, disposed within the p-waveguide layer 18, or partially disposed in both the p-cladding layer 20 and the p-waveguide layer 18.

While this embodiment is directed to the p-side of the 2D-GRSEL 10, it is also possible that the two-dimensional grating 24 may be located on the n-side of the waveguide 32. In other words, the two-dimensional grating 24 may be on the p-side or n-side of the p-i-n semiconductor laser.

If disposed on the n-side of the waveguide 32, the two-dimensional grating 24 may be disposed within the n-waveguide layer 14, disposed between the n-waveguide layer 14 and the n-cladding layer 12, buried within the n-cladding layer 12, or disposed on a bottom of the n-cladding layer, for example. In addition, the two-dimensional grating 24 may be partially buried within the n-waveguide layer 14 and/or the n-cladding layer 12.

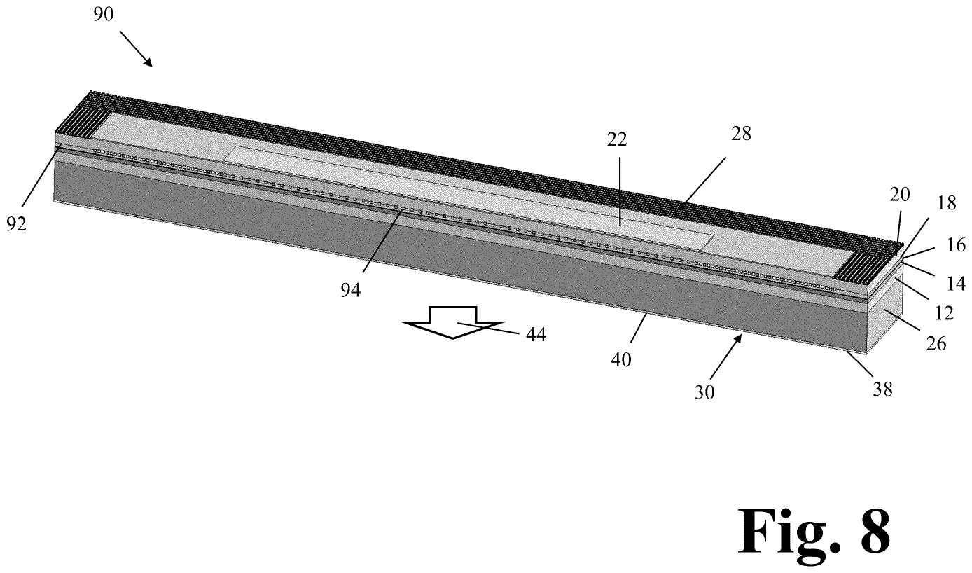

FIG. 8 is a perspective, cross-sectional illustration of a 2D-GRSEL 90 that is similar to the 2D-GRSEL 10, except that the two-dimensional grating 92 is disposed between the p-cladding layer 20 and the p-waveguide layer 18. Here, the two-dimensional grating 92 is contemplated to include holes 94, filled with air, that are partially disposed in the p-waveguide layer 18 and partially disposed in the p-cladding layer 20.

As should be apparent to those skilled in the art, when the two-dimensional grating 92 is buried as illustrated in FIG. 8, the contrast in the indices of refraction between the components of the 2D-GRSEL 90 is achieved by the inclusion of the holes 94 filled with air. Alternatively, as discussed above, the contrast in the indices of refraction may be achieved by filling the holes 94 with a semiconductor material with a different index of refraction than the indices of refraction of the p-waveguide layer 18 and/or the p-cladding layer 20.

As should be apparent from the foregoing discussion, to create holes 94 that are filled with air, the semiconductor materials are first grown to form a partial structure of the p-i-n diode epitaxial structure. Subsequently, nano-lithography may be employed to introduce the air holes 94. The air holes 94 are then covered when the remaining epitaxial layers are grown in subsequent steps without fully filling the air holes 94 with semiconductor material(s).

The 2D-GRSEL 10 and the 2D-GRSEL 90 according to the present invention are not considered to be limited to any particular dimensions. However, selected embodiments may be consistent with one or more of the dimensions provided in Table 1. It is contemplated that the 2D-GRSEL 10, 90 will operate to support an output power in a range of a few watts to 100 watts, depending on the area that is electrically pumped.

TABLE 1
Examples of Various 2D-GRSEL Designs

| | | Examples of Device Designs | | | | | | |
|---|---|---|---|---|---|---|---|---|
| | Unit | Design 1 | Design 2 | Design 3 | Design 4 | Design 5 | Design 6 | Design 7 |
| Stripe _W | (μm) | 150 | 250 | 500 | 300 | 400 | 500 | 500 |
| Stripe_L | (μm) | 1200 | 3000 | 3500 | 3500 | 5000 | 7500 | 8000 |
| Stripe Area | (μm²) | 1.80E+05 | 7.50E+05 | 1.75E+06 | 1.05E+06 | 2.00E+06 | 3.75E+06 | 4.00E+06 |
| Grating_W | (μm) | 250 | 450 | 950 | 600 | 600 | 950 | 700 |
| Grating_L | (μm) | 2400 | 4200 | 4500 | 4500 | 6200 | 9500 | 9000 |
| Chip_W | (μm) | 900 | 1000 | 1350 | 1000 | 1100 | 1350 | 1200 |
| Chip_L | (μm) | 3400 | 5200 | 5300 | 5300 | 7200 | 10300 | 10000 |
| N-window_W | (μm) | 300 | 400 | 650 | 450 | 550 | 650 | 650 |
| N-window_L | (μm) | 2500 | 4300 | 4600 | 4600 | 6300 | 9600 | 9100 |

The discussions of the 2D-GRSEL 10, 90 are intended to provide details about individual examples of 2D-GRSELs according to the present invention. It is noted, however, that multiple 2D-GRSELs may be disposed in a side-by-side configuration without departing from the scope of the present invention.

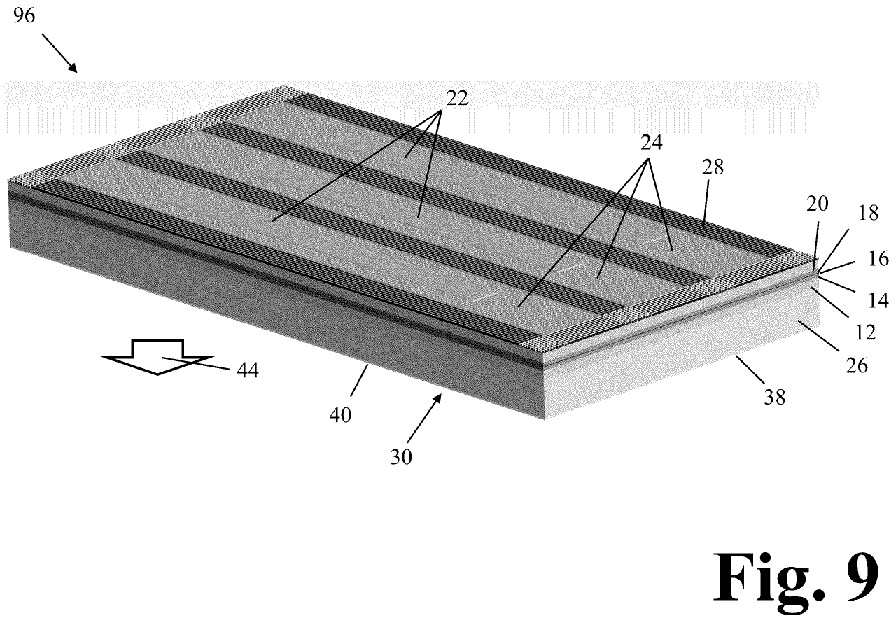

FIG. 9 is a perspective illustration showing one contemplated arrangement where three 2D-GRSELs 10 are disposed in a side-by-side configuration. In this manner, the adjacent 2D-GRSELs 10 may be coherently-coupled to form a combined 2D-GRSEL 96.

The adjacent 2D-GRSELs 10 may be coherently-coupled using two-dimensional grating 24, 92 that is either one dimensional or two dimensional in nature with pitch that is either λ/2n or N/n. In this contemplated embodiment, the coupling is achieved using linear gratings. However two-dimensional gratings 24, 92 may be employed without departing from the scope of the invention. As discussed hereinabove, the pitch(es) of these grating(s) may be λ/2n or λ/n.

It is noted that a one dimensional grating is a type of grating where the index of refraction modulation to form the grating is only in one dimension. A two dimensional grating is a type of grating where the index of refraction modulation is in two dimensions and the gratings in the two different dimensions may or may not be orthogonal to each other.

As also should be apparent, any number of 2D-GRSELs 10 may be coherently coupled to scale up the power of the laser light generated thereby.

It is noted that the two-dimensional grating 24, 92 of the present invention facilitates the creation of a 2D-GRSEL 10, 90, 96 that operates in a single mode. Effectively, the use of a two-dimensional grating 24, 92 causes the 2D-GRSEL 10, 90, 96 to operate in a single mode by shaping and directing the laser light 44 generated by the 2D-GRSEL 10, 90, 96.

When designing a semiconductor laser, it is understood that if the waveguide 32 is made to be thicker, the waveguide will generate a larger number of modes. A larger number of modes results in a brighter laser light. However, multiple modes are akin to the operation of a flashlight in that the modes propagate in multiple directions. One way to think about this is that, if a semiconductor laser operates with twenty modes, the total brightness of the laser light is 20× that of one of the twenty modes. Of course, this also means that the power of a single mode is about 1/20^{th} of the total laser light.

In view of this, a single mode of operation is preferred. When a single mode is generated from a semiconductor laser with a thick waveguide, the single mode will be brighter, among other advantages.

As noted above, in one or more embodiments, the two-dimensional grating 24, 92 in Grating Zone 1 may be configured so that Pₓ=P_{y}=λ/n. In Grating Zone 2, the two-dimensional grating 24, 92 may be configured so that Pₓ=P_{y}=λ/2n. As such, the two-dimensional grating 24, 92 in Grating Zone 2 reflects (or feeds back) light back to Grating Zone 1. And, as noted above, Grating Zone 3 is an absorber area and, therefore, does not reflect light into Grating Zone 2 or Grating Zone 1.

By reflecting the light in this manner and by conditioning the light to encompass a single mode, the 2D-GRSEL 10, 90, 96 is capable of generating a brighter (e.g., more powerful) light in the single mode.

Other advantages of the present invention will be apparent to those skilled in the art.

In view of the many possible embodiments to which the principles of the disclosed technology may be applied, it should be recognized that the illustrated embodiments are only preferred examples and should not be taken as limiting the scope of the disclosure. Variations and equivalents known to those skilled in the art also are contemplated to fall within the scope of the present invention.

1. A two-dimensional grating surface-emitting laser, comprising:
a substrate;
a n-cladding layer disposed atop the substrate;
a n-waveguide layer disposed atop the n-cladding layer;
a p-waveguide layer disposed atop the n-waveguide layer;
a quantum well disposed between the n-waveguide layer and the p-waveguide layer;
a p-cladding layer disposed atop the p-waveguide layer;
a p-contact layer disposed atop the p-cladding layer; and
a two-dimensional grating layer is disposed at a location selected from a group comprising
atop the p-cladding layer,
buried within the p-cladding layer,
between the p-cladding layer and the p-waveguide layer,
buried within the p-waveguide layer,
buried within the n-waveguide layer,
beneath the n-waveguide layer,
between the n-cladding layer and the n-waveguide layer,
buried within the n-cladding layer, and
beneath the n-cladding layer,
wherein the two-dimensional grating layer comprises a plurality of holes arranged in a pattern with a predetermined grating period,
wherein the two-dimensional grating layer defines a first grating zone beneath the p-contact layer, and
wherein the two-dimensional grating layer defines a second grating zone surrounding the first grating zone.

2. The two-dimensional grating surface-emitting laser according to claim 1, wherein the two-dimensional grating layer is disposed atop the p-cladding layer.

3. The two-dimensional grating surface-emitting laser according to claim 1, wherein the two-dimensional grating layer is buried within the p-cladding layer.

4. The two-dimensional grating surface-emitting laser according to claim 1, wherein each of the plurality of holes are filled with air.

5. The two-dimensional grating surface-emitting laser according to claim 1, wherein each of the plurality of holes are filled with a semiconductor material with an index of refraction differing from an index of refraction of the two-dimensional grating layer.

6. The two-dimensional grating surface-emitting laser according to claim 1, wherein each of the plurality of holes are filled with metal.

7. The two-dimensional grating surface-emitting laser according to claim 1, wherein the first grating zone defines a pumped region that generates laser light.

8. The two-dimensional grating surface-emitting laser according to claim 1, wherein the second grating zone defines an unpumped region that does not generate laser light.

9. The two-dimensional grating surface-emitting laser according to claim 1, further comprising a third grating zone surrounding the second grating zone, wherein the third grating zone defines an absorber region that absorbs laser light.

10. The two-dimensional grating surface-emitting laser according to claim 1, wherein:
the predetermined grating period in the first grating zone has a first predetermined period Pₓ in a first direction and a second predetermined period P_{y} in a second direction, orthogonal to the first direction,
$${P}_{x} = {P}_{y} = λ / n ,$$
λ is the wavelength in vacuum, and
n is the effective index of the lasing mode.

11. The two-dimensional grating surface-emitting laser according to claim 1, wherein:
the predetermined grating period in the second grating zone has a first predetermined period Pₓ in a first direction and a second predetermined period P_{y} in a second direction, orthogonal to the first direction,
$${P}_{x} = {P}_{y} = λ / 2 n ,$$
λ is the wavelength in vacuum, and
n is the effective index of the lasing mode.

12. The two-dimensional grating surface-emitting laser according to claim 1, wherein:
the predetermined grating period has a first predetermined period Pₓ in a first direction and a second predetermined period P_{y} in a second direction, orthogonal to the first direction,
$${P}_{x} = λ / n ,$$
$${P}_{y} = λ / 2 n ,$$
λ is the wavelength in vacuum, and
n is the effective index of the lasing mode.

13. The two-dimensional grating surface-emitting laser according to claim 1, wherein, in at least one of the first and second grating zones:
the predetermined grating period has a first predetermined period Pₓ in a first direction and a second predetermined period P_{y} in a second direction, orthogonal to the first direction,
$${P}_{x} = {P}_{y} = λ / n ,$$
λ is the wavelength in vacuum, and
n is the effective index of the lasing mode.

14. The two-dimensional grating surface-emitting laser according to claim 1, wherein, in at least one of the first and second grating zones:
the predetermined grating period has a first predetermined period Pₓ in a first direction and a second predetermined period P_{y} in a second direction, orthogonal to the first direction,
$${P}_{x} = λ / n ,$$
$${P}_{y} = λ / 2 n ,$$
λ is the wavelength in vacuum, and
n is the effective index of the lasing mode.

15. The two-dimensional grating surface-emitting laser according to claim 1, wherein:
in the first grating zone:
the predetermined grating period has a first predetermined period Pₓ in a first direction and a second predetermined period P_{y} in a second direction, orthogonal to the first direction,
$${P}_{x} = {P}_{y} = λ / n ,$$
λ is the wavelength in vacuum, and
n is the effective index of the lasing mode; and
in the second grating zone:
the predetermined grating period has a third predetermined period Pₓ in a first direction and a fourth predetermined period P_{y} in the second direction, and
$${P}_{x} = {P}_{y} = λ / 2 n .$$

16. The two-dimensional grating surface-emitting laser according to claim 1, wherein:
in the first grating zone:
the predetermined grating period has a first predetermined period Pₓ in a first direction and a second predetermined period P_{y} in a second direction, orthogonal to the first direction,
$${P}_{x} = {P}_{y} = λ / n ,$$
λ is the wavelength in vacuum, and
n is the effective index of the lasing mode; and
in the second grating zone:
the predetermined grating period has a third predetermined period Pₓ in a first direction and a fourth predetermined period P_{y} in the second direction, and
$${P}_{x} = λ / n , and$$
$${P}_{y} = λ / 2 n .$$

17. The two-dimensional grating surface-emitting laser according to claim 1, wherein:
the waveguide defines a length L in a first direction,
the waveguide defines a width W in a second direction, orthogonal to the first direction, and
the waveguide defines an aspect ratio m,
$$L / W > m , and$$
$$m > 1.$$

18. The two-dimensional grating surface-emitting laser according to claim 13, wherein:
m is within a range from 1 to 20.

19. The two-dimensional grating surface-emitting laser according to claim 13, wherein:
the width W is within a range of 0.1 mm to 1 mm.

20. The two-dimensional grating surface-emitting laser according to claim 1, further comprising:
an anti-reflective coating on at least a portion of a bottom surface of the substrate.

21. The two-dimensional grating surface-emitting laser according to claim 1, further comprising:
another p-contact layer disposed atop the p-cladding layer,
wherein the another p-contact layer is disposed in a side-by-side relationship to the p-contact layer, thereby establishing a coherently coupled configuration,
wherein the two-dimensional grating layer defines another first grating zone beneath the another p-contact layer, and
wherein the two-dimensional grating layer defines another second grating zone surrounding the another first grating zone.

22. The two-dimensional grating surface-emitting laser according to claim 1, wherein the two-dimensional grating layer comprises an index of refraction modulation that is one dimensional.

23. The two-dimensional grating surface-emitting laser according to claim 1, wherein the two-dimensional grating layer comprises an index of refraction modulation that is two dimensional.
